(19) United States
(12) Patent Application Publication
(10) Pub. No.: US 2013/0344714 A1
(43) Pub. Date: Dec. 26, 2013

(54) CONTACT DEVICE, SOCKET DEVICE AND ELECTRONIC APPARATUS

(71) Applicants: FUJITSU LIMITED, Kawasaki (JP); FUJITSU COMPONENT LIMITED, Tokyo (JP)

(72) Inventors: Takahiro KONDO, Tokyo (JP); Manabu SHIMIZU, Tokyo (JP); Yasushi MASUDA, Kawasaki (JP); Satoshi OHSAWA, Kawasaki (JP); Yoshihiro MORITA, Kawasaki (JP); Akira TAMURA, Kawasaki (JP)

(73) Assignees: FUJITSU LIMITED, Kawasaki (JP); FUJITSU COMPONENT LIMITED, Tokyo (JP)

(21) Appl. No.: 13/921,402

(22) Filed: Jun. 19, 2013

(30) Foreign Application Priority Data
Jun. 20, 2012 (JP) 2012-138974

(51) Int. Cl. H05K 7/20

(52) U.S. Cl. CPC H05K 7/2039
USPC 439/68; 439/487

(57) ABSTRACT

A contact device that electrically connects a first substrate and a second substrate. The contact device includes: a contact that has electrical conductivity and elasticity, the contact including a first terminal that is contactable with a first pad provided on the first substrate and a second terminal that is contactable with a second pad provided on the second substrate, the first terminal and the second terminal being biased in a direction spreading a distance therebetween; and a sheet that has flexibility and heat dissipation, and holds the contact so that the first terminal is arranged opposite to one surface of the sheet and the second terminal is arranged opposite to another surface of the sheet.

### CROSS-REFERENCE TO RELATED APPLICATION

This application is based upon and claims the benefit of priority of the prior Japanese Patent Application No. 2012-138974 filed on Jun. 20, 2012, the entire contents of which are incorporated herein by reference.

### FIELD

A certain aspect of the embodiments is related to a contact device, a socket device, and an electronic apparatus.

### BACKGROUND

There are known a socket using a BGA (Ball Grid Array) type contact (hereinafter referred to as “a BGA socket”) and a socket using a LGA (Land Grid Array) type contact (hereinafter referred to as “a LGA socket”), as a socket which connects a printed circuit board and electronic parts, such as a CPU (Central Processing Unit) and a LSI (Large Scale Integration), to each other.

Although the BGA socket is excellent in signal transfer performance of the electronic parts to be connected and the printed circuit board, a large-scale leased facility is needed for exchange of the electronic parts when the electronic parts have broken down. On the contrary, the LGA socket electrically connects the electronic parts to the printed circuit board by using an electrode pad as a contact. Therefore, when the LGA socket is used, a process that increases the temperature of solder required for the solder fused junction of the BGA socket becomes unnecessary. Moreover, the LGA socket also has a merit that repair work is easy when a failure occurs in the electronic parts.

Japanese Laid-open Patent Publication No. 2003-309230 discloses technology which improves the heat dissipation performance of a heat sink.

### SUMMARY

According to an aspect of the present invention, there is provided a contact device that electrically connects a first substrate and a second substrate, the contact device including: a contact that has electrical conductivity and elasticity, the contact including a first terminal that is contactable with a first pad provided on the first substrate and a second terminal that is contactable with a second pad provided on the second substrate, the first terminal and the second terminal being biased in a direction spreading a distance therebetween; and a sheet that has flexibility and heat dissipation, and holds the contact so that the first terminal is arranged opposite to one surface of the sheet and the second terminal is arranged opposite to another surface of the sheet.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating the construction of a contact device;

FIG. 2 is a diagram illustrating a state where the contact device is inserted between an IC (Integrated Circuit) package and a printed circuit board, and the contact device, the IC package and the printed circuit board are screwed;

FIG. 3 is a diagram illustrating a contact alone;

FIG. 4 is a diagram illustrating a state where a plurality of contacts arranged in the shape of a lattice are held with a sheet;

FIG. 5 is a diagram illustrating another configuration of the sheet;

FIG. 6A is a diagram illustrating another configuration of the contact;

FIG. 6B is a diagram illustrating a state where the contact device including the contact illustrated in FIG. 6A is inserted between the IC (Integrated Circuit) package and the printed circuit board, and the contact device, the IC package and the printed circuit board are screwed;

FIG. 7 is an exploded perspective view illustrating an electronic apparatus;

FIG. 8A is a perspective view illustrating the IC package and a socket body of a LGA socket;

FIG. 8B is a diagram illustrating a state where the IC package is mounted on the socket body of the LGA socket;

FIG. 9 is a cross-section diagram illustrating a state where the IC package is mounted on the printed circuit board;

FIG. 10A is a perspective view illustrating the IC package, and the LGA socket in which the sheet protrudes from an outer frame to the outside;

FIG. 10B is a lateral view of the IC package and the LGA socket illustrated in FIG. 10A;

FIG. 11A is a perspective view illustrating the IC package, and the LGA socket in which the sheet protruded to the outside of the outer frame is folded back and covers an upper surface of the IC package; and

FIG. 11B is a lateral view of the IC package and the LGA socket illustrated in FIG. 11A.

### DESCRIPTION OF EMBODIMENTS

In the above-mentioned technology, enlargement of the printed circuit board may generate a warp in the printed circuit board by a manufacturing error. When the printed circuit board in which the warp has been generated is connected to the electronic parts by using the LGA socket, the LGA socket cannot absorb the warp of the printed circuit board, and hence a problem may arise in the reliability of connection. Moreover, since the electronic parts generate heat, a measure for the heat is also needed.

Hereinafter, a description will be given of embodiments of the present invention with reference to the drawings.

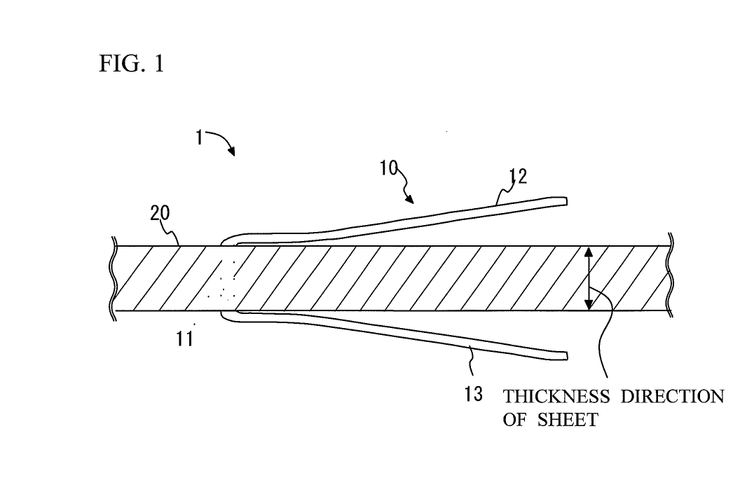

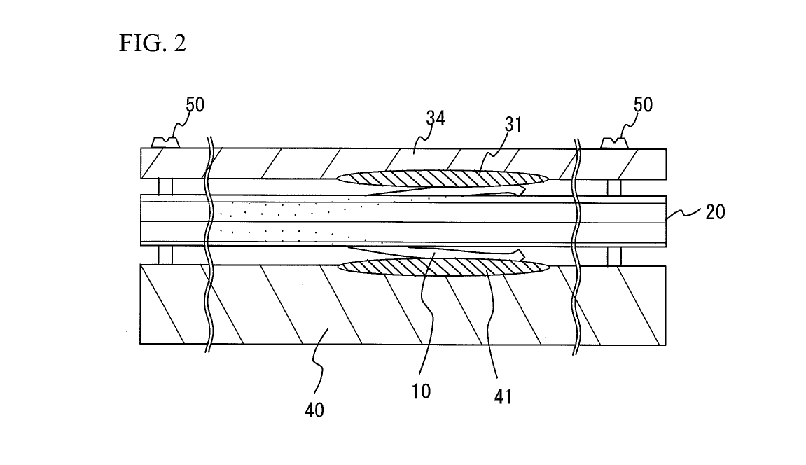

First, a description will be given of an embodiment of a contact device. FIG. 1 is a diagram illustrating the main construction of the contact device 1. FIG. 2 is a cross-section diagram illustrating a state where boards electrically connected to each other are fixedly screwed.

The contact device 1 includes a contact 10 and a sheet 20, as illustrated in FIG. 1. The contact 10 is fixed to the sheet 20, or is held by the sheet 20. A fixing method or a holding method of the contact 10 by the sheet 20 is described later. The contact 10 is an elastic member including a first terminal 12 and a second terminal 13. One ends of the first terminal 12 and the second terminal 13 are coupled with each other, and the first terminal 12 and the second terminal 13 are biased in a direction spreading a distance between the first terminal 12 and the second terminal 13. The sheet 20 is a member which fixes or holds the contact 10. The sheet 20 fixes or holds the contact 10 so that the first terminal 12 is opposite to the second terminal 13 via the sheet 20.

The contact device 1 having the above-mentioned construction is sandwiched between a substrate (i.e., a first substrate) 34 of the IC package as an electronic part which is arranged in opposition to the contact device 1, and the printed circuit board 40 (i.e., a second substrate). Then, the contact device 1 electrically connects the substrate 34 of the IC package to the printed circuit board 40. Here, in FIG. 2, the thickness of the sheet 20 is exaggeratingly illustrated in order to clarify a contact state between the substrate 34 of the IC package in the contact device 1 and the printed circuit board 40.

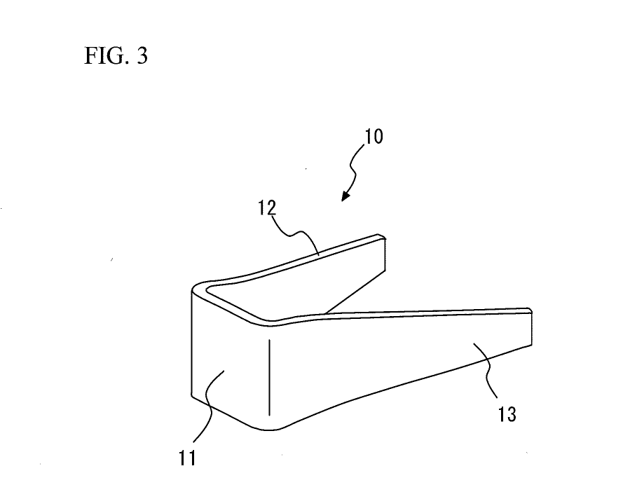

Next, a description will be given of the contact 10 in detail with reference to FIG. 3. FIG. 3 is a diagram illustrating the contact 10 alone.

The contact 10 includes a base unit 11, the first terminal 12, and the second terminal 13, as illustrated in FIG. 3. The contact 10 is made of a conductive material, such as metal alloy having an elastic force (e.g. copper alloy).

The base unit 11 is a tabular member, and is fixed to the sheet 20 or held by the sheet 20 in a direction parallel with a thickness direction of the sheet 20. The first terminal 12 is a contact unit that contacts a first pad 31 formed on the substrate 34 of the IC package. The second terminal 13 is a contact unit that contacts a second pad 41 formed on the printed circuit board 40.

The first terminal 12 and the second terminal 13 are connected to the base unit 11 so that a cross-section surface of the contact 10 becomes substantially a horseshoe shape. In addition, the first terminal 12 and the second terminal 13 are extended from both ends of the base unit 11, respectively, so that the first terminal 12 is arranged near one surface of the sheet 20 and the second terminal 13 is arranged near another surface of the sheet 20 opposite to the one surface thereof That is, the first terminal 12 is arranged opposite to the one surface of the sheet 20 and the second terminal 13 is arranged opposite to the another surface of the sheet 20. When the contact 10 is fixed to the sheet 20, the base unit 11 is fixed to the sheet 20 so that the first terminal 12 and the second terminal 13 sandwich the sheet 20.

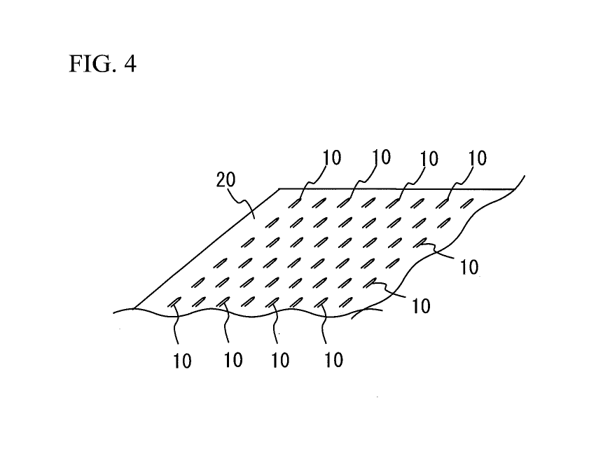

Next, a description will be given of the sheet 20. The sheet 20 is made of resin, such as silicon, for example. The sheet 20 fixes or holds a plurality of contacts 10 arranged in a lattice form, as illustrated in FIG. 4. Each of the contacts 10 arranged in the lattice form on the sheet 20 contacts the first pad 31 formed on a lower surface of the substrate 34 of the IC package, and the second pad 41 formed on an upper surface of the printed circuit board 40. Thereby, the IC package is electrically connected to the printed circuit board 40.

The sheet 20 has heat dissipation. When the sheet 20 is sandwiched between the substrate 34 of the IC package and the printed circuit board 40, the sheet 20 contacts or is contactable with at least one of the substrate 34 of the IC package and the printed circuit board 40. Therefore, heat of at least one of the IC package and the printed circuit board 40 can be radiated with the sheet 20 having heat dissipation.

The sheet 20 may have thermal conductivity. The heat of the IC package transmitted through the contacts 10 is conducted to a heat dissipation plate (not shown) and a heat sink (not shown) which are connected to the sheet 20, or a ground pattern on the substrate (not shown), via the sheet 20. Thereby, the IC package is cooled.

Next, a description will be given of electrical connection between the substrate and the printed circuit board using the contacts 10. In order to stably and electrically connect the substrate 34 of the IC package to the printed circuit board 40 by the contacts 10, an elastic body in the form of a plate spring is used as each contacts 10. The reason for having used the elastic body for each contact 10 is explained below.

When the printed circuit board 40 is a large-sized printed circuit board, the warp may occur in the large-sized printed circuit board 40. Even when the printed circuit board 40 is not the large-sized printed circuit board, the warp may occur in the printed circuit board 40 by the manufacturing error, the heat or an external force. When the IC package is connected to the printed circuit board 40 in which the warp has occurred, the contact failure may occur in connection portions of the contacts 10 which electrically connect the IC package to the printed circuit board 40. Therefore, the elastic body in the form of the plate spring is used as each contact 10 in order to cancel the electric contact failure. The first terminal 12 and the second terminal 13 of each contact 10 are biased in the direction spreading the distance between the first terminal 12 and the second terminal 13. That is, the first terminal 12 is biased so as to spread upward relative to the sheet 20, and the second terminal 13 is biased so as to spread downward relative to the sheet 20. Therefore, even if the warp occurs in the substrate 34 of the IC package or the printed circuit board 40, when the warp is within an elastic deformable range of the first terminal 12 and the second terminal 13, the first terminal 12 can be electrically connected to the first pad 31 and the second terminal 13 can be electrically connected to the second pad 41.

Then, when the contact 10 is sandwiched between the substrate 34 of the IC package and the printed circuit board 40, the first terminal 12 contacts the first pad 31 of the IC package, receives a downward force toward the sheet 20, and is elastically deformed downwardly (toward the sheet 20), as compared with a normal state of no reception of the force (see FIGS. 1 and 2). Similarly, the second terminal 13 contacts the second pad 41 of the printed circuit board 40, receives a upward force toward the sheet 20, and is elastically deformed upwardly (toward the sheet 20), as compared with the normal state of no reception of the force (see FIGS. 1 and 2). When the first terminal 12 is elastically deformed, a contact area of the first terminal 12 and the first pad 31 increases, so that the first terminal 12 and the first pad 31 can be stably and electrically connected. Similarly, when the second terminal 13 is elastically deformed, a contact area of the second terminal 13 and the second pad 41 increases, so that the second terminal 13 and the second pad 41 can be stably and electrically connected.

By using a member having flexibility as the sheet 20, it is also possible to cope with the warp of the substrate 34 of the IC package or the printed circuit board 40. For example, the substrate 34 of the IC package or the printed circuit board 40 are electrically connected by the contacts 10, and are fixedly screwed with screws 50, as illustrated in FIG. 2. By screw cramp of the screws 50, the contacts 10 are pressure-coupled between the substrate 34 of the IC package and the printed circuit board 40. However, since the sheet 20 has flexibility, even when the warp occurs in the substrate 34 of the IC package and the printed circuit board 40, the sheet 20 can be flexibly deformed along the warp. Therefore, in the electric connection between the substrate 34 of the IC package and the printed circuit board 40, the occurrence of the contact failure can be reduced.

Next, a description will be given of a manufacturing method of the contact device 1 and a fixed method of the contact 10 to the sheet 20. First, the contacts 10 are loaded into a metallic mold, and resin such as silicon is poured into the metallic mold. Then, the contacts 10 are wrapped by melted resin, and are solidified. That is, the contact device 1 is manufactured by insert molding. Thereby, the contacts 10 are fixed into the sheet 20. Here, the resin to be used as the sheet 20 is not limited to silicon, and may be resin which can be molded by a mold and resin having thermal conductivity or heat dissipation.

Next, a description will be given of a method for holding the contacts 10 by the sheet 20. By press processing or laser processing, holes are punched at predetermined positions for fixing the contacts 10 of the sheet 20 obtained by metal rolling in the shape of a film. The contacts 10 are press into the punched holes. In this case, it is desirable that the contacts 10 do not fall off the sheet 20 by making the length in a sheet thickness direction of the base unit 11 of each contact 10 and the thickness of the sheet 20 almost the same, and by sandwiching the sheet 20 between root portions of the first terminal 12 and the second terminal 13.

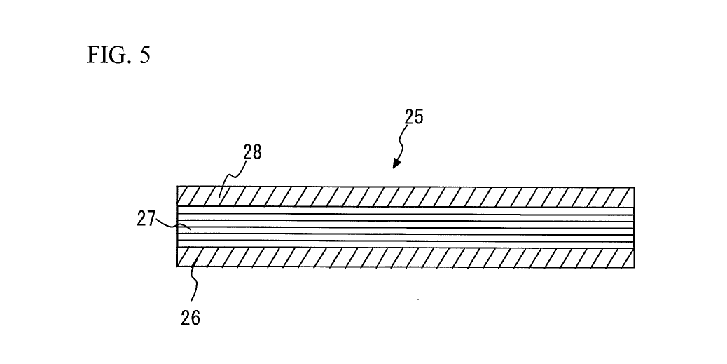

FIG. 5 illustrates another configuration of the sheet 20. A sheet 25 in FIG. 5 as another configuration includes a first layer 26, a second layer 27, and a third layer 28. The first layer 26 and the third layer 28 as the outer surface have heat dissipation. The second layer 27 sandwiched between the first layer 26 and the third layer 28 is a core member of the sheet 25, and synthetic resin which has flexibility, such as acrylic resin and PET (polyethylene telephthalate), can be used as the second layer 27. In addition, on condition that the second layer 27 is insulated from the contacts 10, carbon or metal can also be used as the second layer 27. Since the sheet 25 includes the second layer 27 as the core member, the intensity of the sheet 25 increases. The first layer 26 and the third layer 28 which have the heat dissipation performance can radiate the heat which has arisen in the IC package 30 through the contact 10. Here, the shape of the sheet 25 may be the same as the shape of the bottom of the socket.

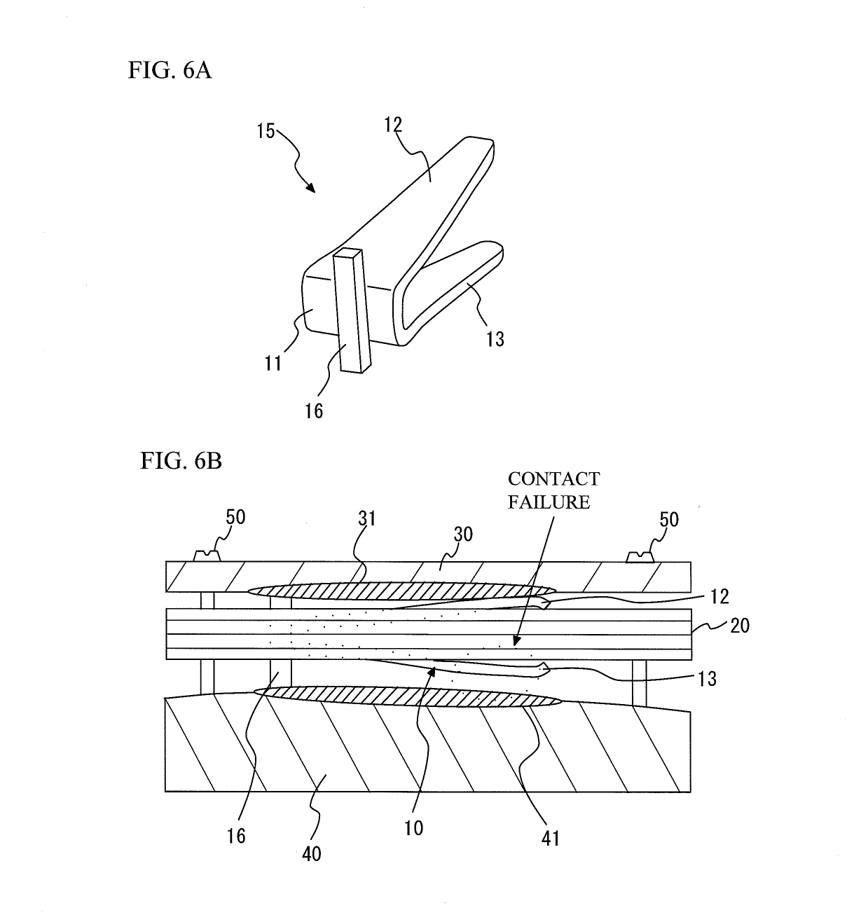

FIGS. 6A and 6B illustrate another configuration of each contact 10. A contact 15 as another configuration of each contact 10 includes a third terminal 16 with the shape of a post in a surface of the base unit 11 opposite to a surface of the base unit 11 to which the first terminal 12 and the second terminal 13 are fixed, as illustrated in FIG. 6A. The third terminal 16 extends in the thickness direction of the sheet 20. In a state where the contact 15 is held by the sheet 20, the third terminal 16 protrudes from both of the upper surface and the lower surface of the sheet 20 so as to contact the first pad 31 of the IC package 30 and the second pad 41 of the printed circuit board 40.

FIG. 6B illustrates a state where the warp exceeding an elastic deformable range of the contact 15 has occurred in the printed circuit board 40, and the contact failure has occurred between the second terminal 13 and the second pad 41. Even in such a state, the first pad 31 and the second pad 41 are electrically connected by the third terminal 16 provided in the thickness direction of the sheet 20, and hence the contact failure between the IC package 30 and the printed circuit board 40 can be prevented.

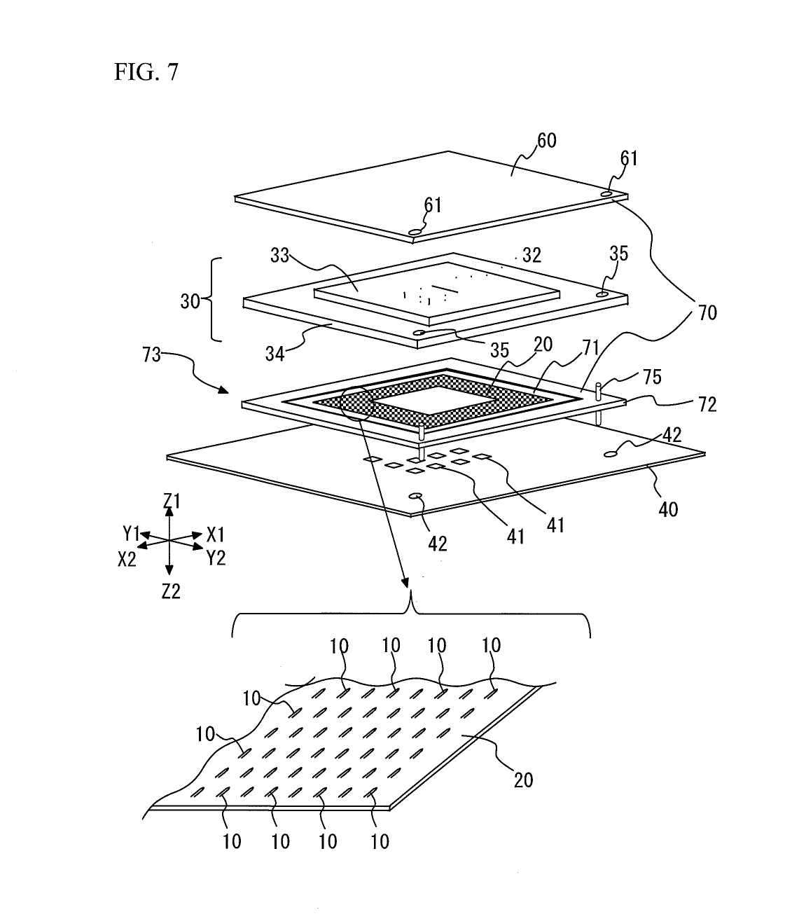

A description will be given of the configuration of an electronic apparatus in which the IC package 30 and the printed circuit board 40 are connected by a LGA (Land Grid Array) socket 70 including the above-mentioned contact device 1, with reference to FIG. 7. Here, FIG. 7 is an exploded perspective view illustrating the electronic apparatus.

In the IC package 30, an IC chip 32 is mounted on the substrate 34, and the circumference of the IC chip 32, including an upper surface and side surfaces of the IC chip 32, mounted on the substrate 34 is sealed by a seal resin material 33.

The LGA socket 70 includes a socket body 73 and a cover member 60 which is a cover of the socket body 73. The socket body 73 includes the contact device 1, a base member 71, and an outer frame 72 surrounding the circumference of the base member 71. The IC package 30 is housed in the socket body 73 and covered with the cover member 60 from above. Thereby, the IC package 30 is housed in the LGA socket 70. The base member 71 electrically connects the contact device 1 to the printed circuit board 40.

The contact device 1 includes the sheet 20 on which the contacts 10 are arranged in X and Y directions at given intervals in order to electrically connect a plurality of first pads 31 (not shown) formed on the lower surface of the substrate 34 of the IC package 30 to a plurality of second pads 41 formed on the upper surface of the printed circuit board 40. The IC package 30 and the printed circuit board 40 are electrically connected by the contact device 1.

Next, a description will be give of the attachment of the IC package 30 and the LGA socket 70 to the printed circuit board 40. First, the socket body 73 is placed on the printed circuit board 40. Positioning members 75 for positioning are provided on the socket body 73, as illustrated in FIG. 7. Then, mounting holes 42 into which the positioning members 75 are inserted are provided on the printed circuit board 40. By inserting the positioning members 75 into the mounting holes 42, the socket body 73 is mounted on the printed circuit board 40. At this time, the second terminal 13 of the contact device 1 is connected to the second pad 41 of the printed circuit board 40.

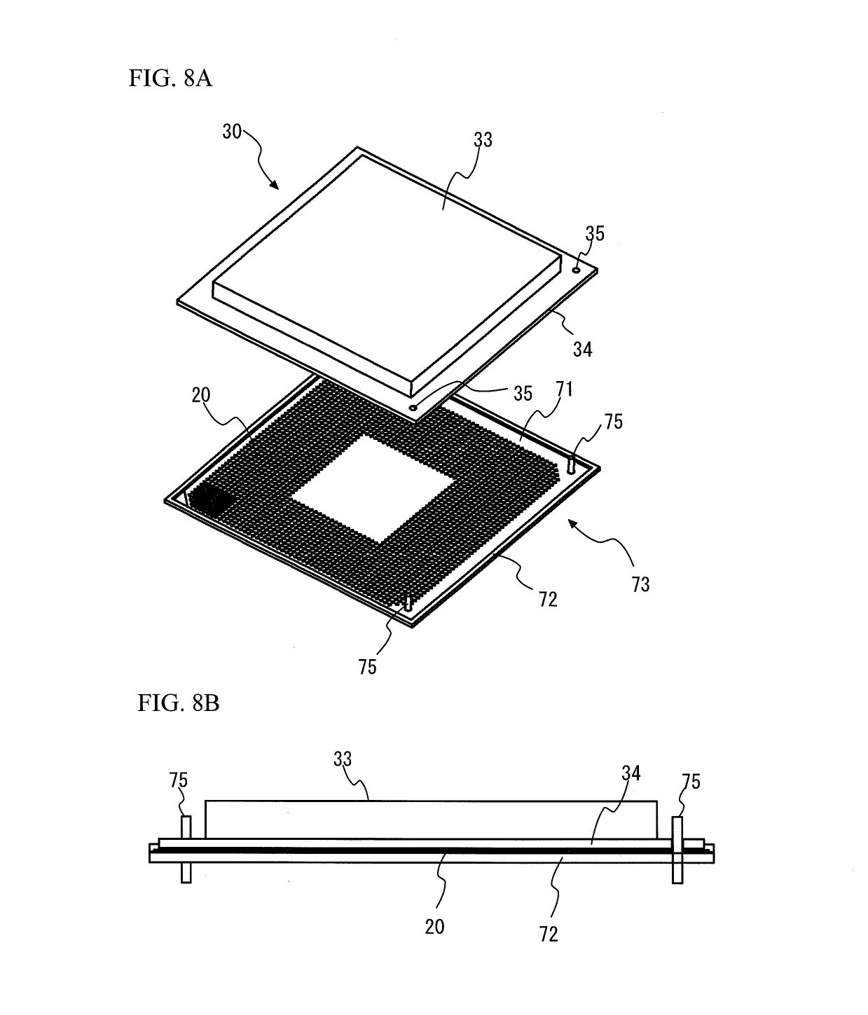

By fitting the IC package 30 in the inside of the outer frame 72, the IC package 30 is placed on the contact device 1. FIG. 8A is a perspective view illustrating the IC package 30, and the socket body 73 before the IC package 30 is placed. FIG. 8B illustrates a state where the IC package 30 is placed on the base member 71. As illustrated in FIGS. 8A and 8B, mounting holes 35 are provided also on the IC package 30. By inserting the positioning members 75 of the socket body 73 into the mounting holes 35, the IC package 30 can be easily mounted on the socket body 73. As illustrated in FIG. 7, mounting holes 61 are provided also on the cover member 60 of the LGA socket 70, and hence the cover member 60 can be easily mounted on the socket body 73 on which the IC package 30 has been mounted.

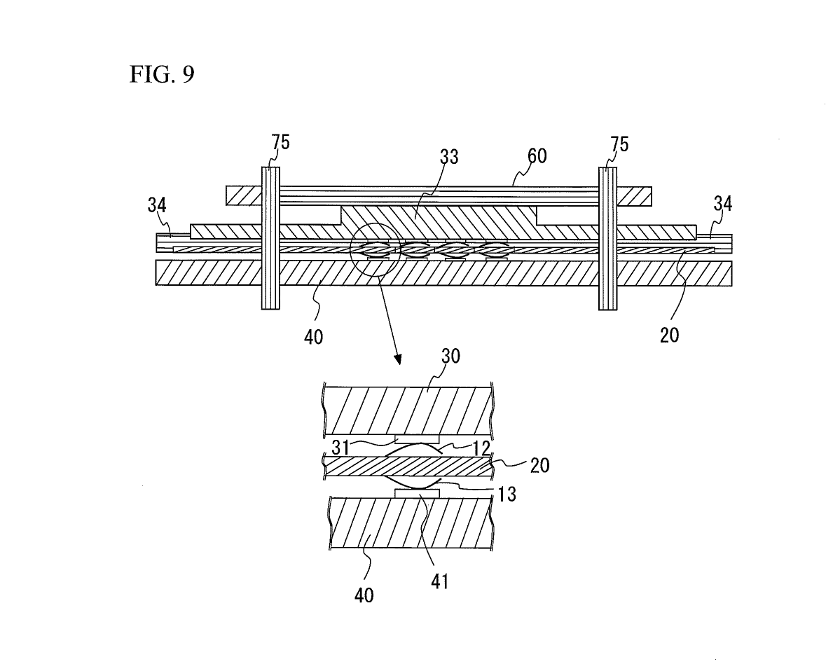

FIG. 9 is a cross-section diagram illustrating a state where the IC package 30 is mounted on the printed circuit board 40 by using the LGA socket 70. In this mounting state, each first terminal 12 protruded at an upper surface side of the sheet 20 contacts each first pad 31 formed on the lower surface of the substrate 34, and each second terminal 13 protruded at a lower surface side of the sheet 20 contacts each second pad 41 on the printed circuit board 40. When the IC package 30 is mounted on the socket body 73, the first terminal 12 of the contact device 1 is pressed on the side of the sheet 20 while sliding on the first pad 31 of the IC package 30. At this time, the second terminal 13 which contacts the second pad 41 is also pressed on the side of the sheet 20. Therefore, the contact area of the first terminal 12 and the first pad 31 and the contact area of the second terminal 13 and the second pad 41 increase, so that the first terminal 12 and the first pad 31, and the second terminal 13 and the second pad 41 can be stably and electrically connected. Then, the cover member 60 is placed on the IC package 30, so that the electronic apparatus in which the IC package 30 and the LGA socket 70 are placed on the printed circuit board 40 is completed.

Here, when the third terminal 16 is provided in the contact device 1, it is desirable that the length of the third terminal 16 is adjusted and a distance between the base member 71 and the IC package 30 is set to 0.3 to 0.5 mm (i.e., height corresponding to BGA), in order to improve electrical characteristics. Here, holes can be punched in the sheet 20 and the positioning can also be performed through pins.

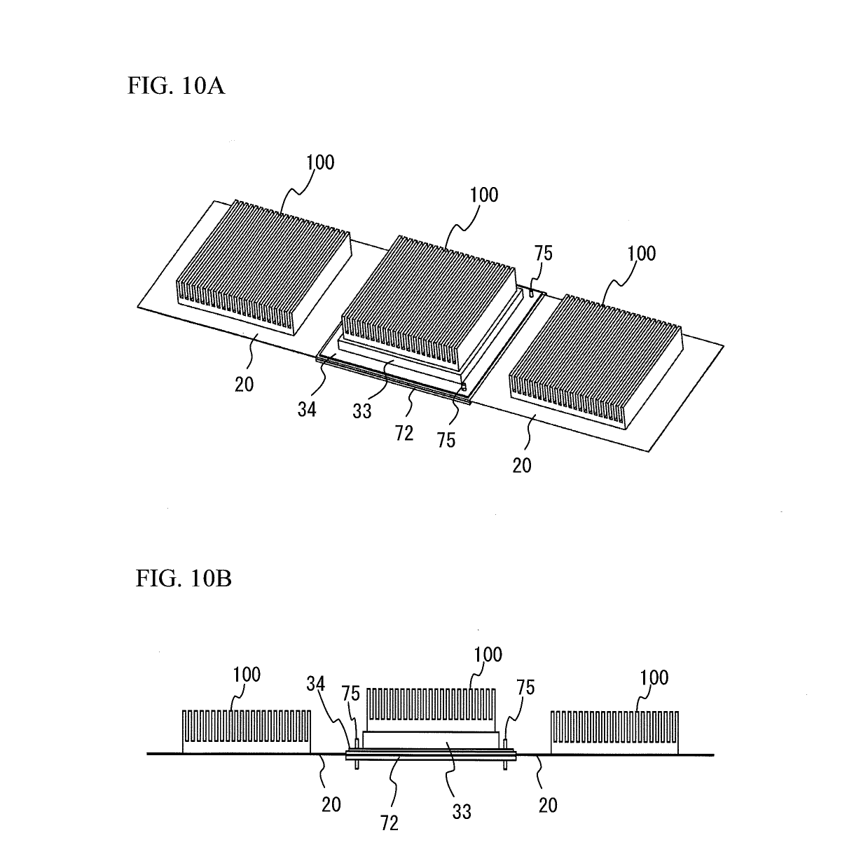

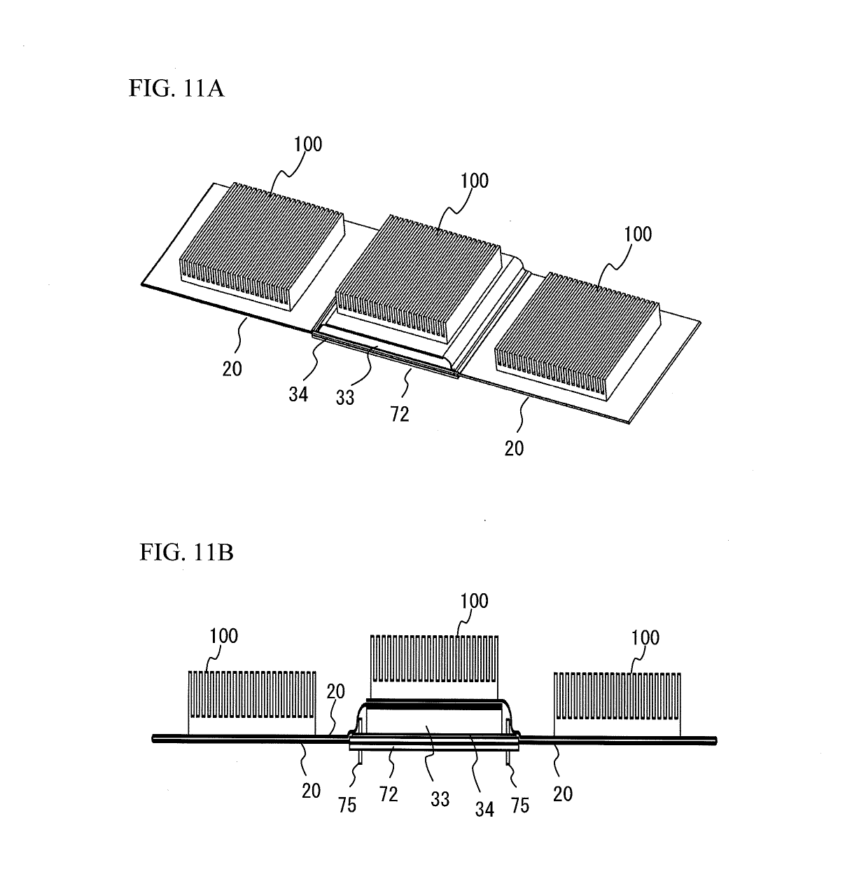

A description will be given of another embodiments of the sheet 20, with reference to FIGS. 10A to 11B. FIGS. 10A and 11A are perspective views illustrating the LGA socket 70 on which the IC package 30 is mounted. FIGS. 10B and 11B are lateral views illustrating the LGA socket 70 on which the IC package 30 is mounted.

In an example of FIGS. 10A and 10B, the length of the sheet 20 is sufficiently longer than that of one side of the outer frame 72, and the sheet 20 protrudes to the outsides of the outer frame 72 from two opposed sides of the outer frame 72. A plurality of heatsinks 100 for heat dissipation are fixedly arranged on the upper surface of the sheet 20 which is located on the outsides of the outer frame 72. The heatsink 100 is placed also on the upper surface of the IC package 30 (here, in FIGS. 10A to 11B, the seal resin material 33 and the substrate 34 illustrated as the IC package 30), and the heat of the IC package 30 is radiated. The sheet 20 having the thermal conductivity is drawn out to the outside of the socket body 73 and the heatsinks 100 are fixedly arranged on the drawn-out sheet 20, so that the heat of the IC package 30 can be efficiently radiated to the outside.

In an example of FIGS. 11A and 11B, the sheet 20 protruded to the outsides of the outer frame 72 is folded back toward the IC package 30, and the folded sheet 20 covers the upper surface of the IC package 30. In FIG. 11B, the upper surface of the seal resin material 33 is covered. The heatsink 100 is arranged on the sheet 20 which has covered the upper surface of the IC package 30. The upper surface of the IC package 30 is covered by the sheet 20 having the heat dissipation, so that the heat which arises in the IC package 30 can be further efficiently radiated to the outside.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A contact device that electrically connects a first substrate and a second substrate, the contact device comprising:
a contact that has electrical conductivity and elasticity, the contact including a first terminal that is contactable with a first pad provided on the first substrate and a second terminal that is contactable with a second pad provided on the second substrate, the first terminal and the second terminal being biased in a direction spreading a distance therebetween; and
a sheet that has flexibility and heat dissipation, and holds the contact so that the first terminal is arranged opposite to one surface of the sheet and the second terminal is arranged opposite to another surface of the sheet.

2. The contact device as claimed in claim 1, wherein when the sheet is sandwiched between the first substrate and the second substrate, the sheet contacts at least one of the first substrate and the second substrate.

3. The contact device as claimed in claim 1, wherein the sheet includes: a core material having flexibility; and materials sandwiching the core material and having heat dissipation.

4. The contact device as claimed in claim 1, wherein the sheet has thermal conductivity, the sheet protrudes to the outside of a connection part between the first substrate and the second substrate, and a heat dissipation member is arranged on the protruded sheet.

5. The contact device as claimed in claim 1, wherein the contact includes:
a base unit that is held by the sheet, the first terminal and the second terminal being extended from both ends of the base unit, respectively; and
a third terminal that is fixed to the base unit, extends in a thickness direction of the sheet, and is connected to the first terminal and the second terminal.

6. The contact device as claimed in claim 1, wherein the first substrate is a bottom of an IC (Integrated Circuit) package, and the sheet contacts the bottom of the IC package.

7. A socket device comprising:
a contact device that electrically connects an IC (Integrated Circuit) package and a printed circuit board, the contact device including:
a contact that has electrical conductivity and elasticity, the contact including a first terminal that is contactable with a first pad provided on the IC package and a second terminal that is contactable with a second pad provided on the printed circuit board, the IC package and the printed circuit board being biased in a direction spreading a distance therebetween; and
a sheet that has flexibility and heat dissipation, and holds the contact so that the first terminal is arranged opposite to one surface of the sheet and the second terminal is arranged opposite to another surface of the sheet;
a base member that electrically connects the contact device to the printed circuit board; and
a cover member that covers the IC package placed on the contact device.

8. An electronic apparatus comprising:
an IC (Integrated Circuit) package;
a printed circuit board that is electrically connected to the IC package; and
a socket device;
the socket device including:
a contact device that electrically connects the IC package and the printed circuit board;
a base member that electrically connects the contact device to the printed circuit board; and
a cover member that covers the IC package placed on the contact device;
the contact device including:
a contact that has electrical conductivity and elasticity, the contact including a first terminal that is contactable with a first pad provided on the IC package and a second terminal that is contactable with a second pad provided on the printed circuit board, the IC package and the printed circuit board being biased in a direction spreading a distance therebetween; and
a sheet that has flexibility and heat dissipation, and holds the contact so that the first terminal is arranged opposite to one surface of the sheet and the second terminal is arranged opposite to another surface of the sheet.
